(19) United States
(12) Patent Application Publication
(10) Pub. No.: US 2016/0374204 A1
(43) Pub. Date: Dec. 22, 2016

(54) CIRCUIT BOARD, ELECTRONIC APPARATUS COMPRISING CIRCUIT BOARD, AND METHOD FOR SOLDERING COMPONENTS

(71) Applicant: Kabushiki Kaisha Toshiba, Tokyo (JP)

(72) Inventor: Yasumichi Miyazaki, Ome Tokyo (JP)

(21) Appl. No.: 15/053,373

(22) Filed: Feb. 25, 2016

Related U.S. Application Data
(60) Provisional application No. 62/181,467, filed on Jun. 18, 2015.

(51) Int. Cl. H05K 1/18; H05K 3/34; H05K 1/11

(52) U.S. Cl. CPC H05K 1/181; H05K 1/111; H05K 3/341; H05K 2201/10015

(57) ABSTRACT

According to one embodiment, a circuit board includes a land to which a component is soldered. The land includes a first land to which a solder base is mounted, and a second land integrated with the first land. The second land has a width less than a width of a connection terminal. The solder base provided on the first land melts and flows into a gap between the second and land by capillary action. The component is attached to the circuit board with the solder that has flowed in.

### CROSS-REFERENCE TO RELATED APPLICATIONS

This application claims the benefit of U.S. Provisional Application No. 62/181,467, filed Jun. 18, 2015, the entire contents of which are incorporated herein by reference.

### FIELD

Embodiments described herein relate generally to a circuit board comprising components soldered thereto, an electronic apparatus comprising the circuit board, and a method for soldering the components.

### BACKGROUND

Electronic apparatuses comprise circuit boards provided with various components mounted thereon. The components are generally attached to the circuit boards by means of soldering. The components are soldered, for example, in the following manner.

Cream solder is applied to electrodes (lands) formed on a circuit board, and components are provided on the applied solder paste. The circuit board is then heated in a reflow oven or the like so that the solder paste melts between the lands and the components. After the solder melts, the circuit board is cooled to solidify the molten solder, and in this way, the components are attached to the circuit board.

In the above-described method, however, there are some cases where the mounting heights of the components increase when a more than necessary amount of solder paste is applied to the circuit board or the components are lifted by bubbles arising from the molten solder.

Therefore, in conventional techniques, a housing to be provided above the circuit board is provided at a sufficient height so that the components will not contact the housing and the like. Consequently, an unnecessary space is formed between the circuit board and the housing, which prevents reduction in the thickness of the electronic apparatus.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is a perspective view of a tablet computer comprising a circuit board of an embodiment.

FIG. 2 is a perspective view of a part of a circuit board of a first embodiment.

FIG. 3 is a side view of a part of the circuit board of the first embodiment.

FIG. 4 is a side view of a part of the circuit board of the first embodiment.

FIG. 5 is a plan view of a part of the circuit board of the first embodiment.

FIG. 6 is a perspective view of a part of the circuit board of the first embodiment.

FIG. 7 is a side view of a part of the circuit board of the first embodiment.

FIG. 8 is a perspective view of a part of a circuit board of a second embodiment.

FIG. 9 is a perspective view of a part of a circuit board of a third embodiment.

FIG. 10 is a side view of a part of the circuit board of the third embodiment.

FIG. 11 is a perspective view of a part of the circuit board of the fourth embodiment.

FIG. 12 is a perspective view of a part of a circuit board of a fifth embodiment.

FIG. 13 is a perspective view of a part of a circuit board of a sixth embodiment.

FIG. 14 is a perspective view of a part of a circuit board of a seventh embodiment.

FIG. 15 is a perspective view of a part of a circuit board of an eighth embodiment.

### DETAILED DESCRIPTION

Various embodiments will be described hereinafter with reference to the accompanying drawings.

In general, according to one embodiment, a circuit board comprises various components soldered thereto. The circuit board is incorporated, for example, in an electronic apparatus.

### First Embodiment

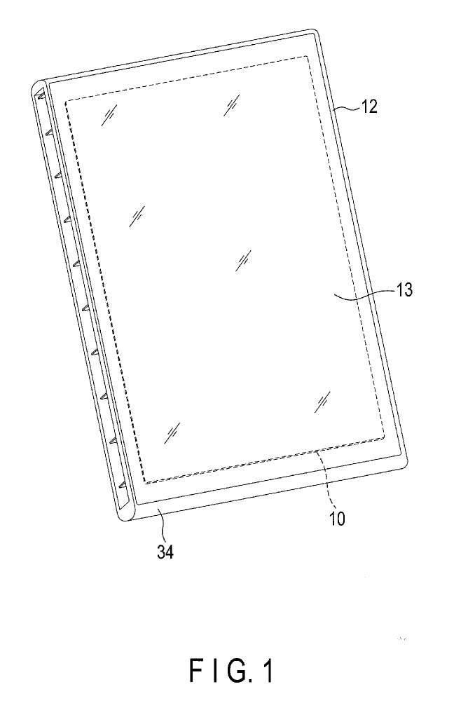

FIG. 1 is a perspective view of an electronic apparatus comprising a circuit board 10 of an embodiment, namely, a tablet computer 12. The tablet computer 12 is an image display device comprising an image display surface 13 provided thereon, and further comprising the circuit board 10 in a housing 34. Note that the electronic apparatus of the present embodiment is not necessarily limited to the tablet computer 12.

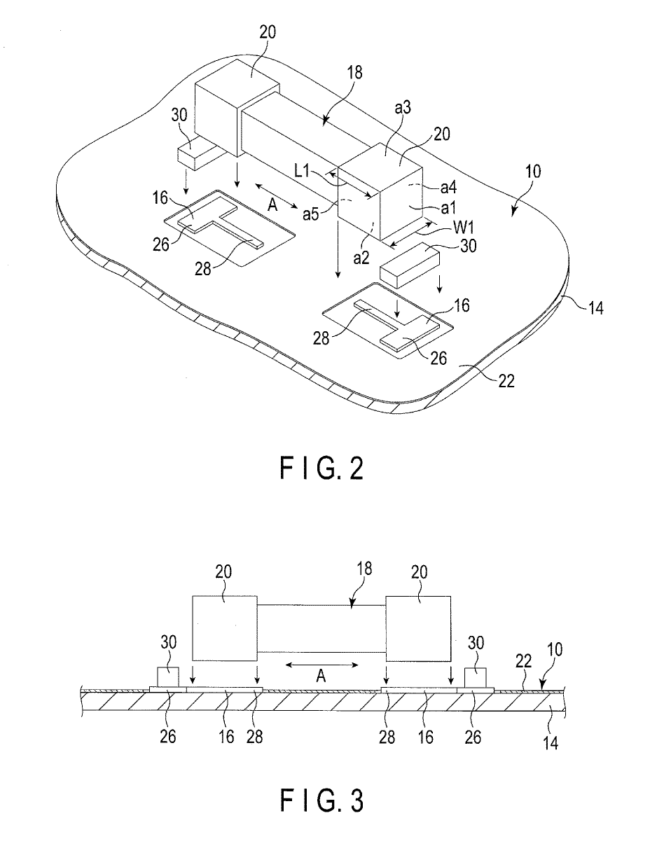

FIG. 2 illustrates a part of the circuit board 10. The circuit board 10 comprises, as shown in FIG. 2, lands 16 on the surface of a plate-like member 14 formed of an insulating resin material. To the lands 16, a component, namely, a ceramic capacitor 18 is to be attached.

First, the ceramic capacitor 18 will be described. The ceramic capacitor 18 is, as shown in FIGS. 3 and 5, substantially a rectangular parallelepiped the longitudinal direction of which is indicated by arrow A. The fracture cross-section of the ceramic capacitor 18 taken perpendicularly to the longitudinal direction is substantially a square. The ceramic capacitor 18 comprises connection terminals 20 formed of a metal thin film and provided in the respective longitudinal end portions.

Each of the connection terminals 20 has a length L1 in the longitudinal direction and a width W1 in a direction perpendicular to the longitudinal direction. Further, the connection terminal 20 comprises an outer terminal surface a1 provided on a longitudinal end surface of the ceramic capacitor 18, a lower terminal surface a2 provided at the bottom, an upper terminal surface a3 provided on top, a right terminal surface a4 provided on the right-hand side, and a left terminal surface a5 provided on the left-hand side. Each of the connection terminals 20 is connected to an internal electrode of the ceramic capacitor 18. Note that the component is not limited to the ceramic capacitor 18.

The lands 16 are provided in attachment positions on the circuit board 10 to which the ceramic capacitor 18 is to be attached. The lands 16 are provided in pairs and corresponding to the connection terminals 20 of the ceramic capacitor 18. The lands 16 in a pair are symmetrically arranged. Now, one of the lands 16 in a pair will be described in detail.

The land 16 is a part of a conductive metal pattern formed on the surface of the plate-like member 14. The land 16 comprises a first land, namely, a solder loading land 26, and a second land, namely, an attachment land 28. The solder loading land 26 and the attachment land 28 are arranged in such a manner as to form substantially a T shape.

The solder loading pat 26 has, as shown in FIG. 5, a substantially rectangular shape in a planar view. The solder loading land 26 is, when the ceramic capacitor 18 is provided in the attachment positions on the circuit board 10, located on the outer side of the longitudinal ceramic capacitor 18, which is a more outer side than the outer terminal surface a1 of the longitudinal ceramic capacitor 18.

The attachment land 28 is provided substantially in the center of the solder loading land 26. The attachment land 28 has a width W2 and a length L2, and extends in the longitudinal direction of the ceramic capacitor 18. The attachment land 28 has width W2 less than width W1 of the connection terminal 20 and length L2 slightly greater than length L1 of the longitudinal connection terminal 20. Note that length L2 of the attachment land 28 may be equal to length L1 of the longitudinal connection terminal 20 or may be less than length L1 of the longitudinal connection terminal 20.

To the circuit board 10, a film having electric insulation, namely, an insulating film 22 is applied. The insulating film 22 is applied to the circuit board 10 in such a manner as to expose the lands 16 at the surface of the circuit board 10.

On the solder loading land 26, a solder base, namely, solder paste 30 is provided. The solder paste 30 is a pastry member containing granular metal solder, and is liquefied as the granular solder contained therein melts at a predetermined temperature. The solder paste 30 is applied to predetermined positions of the circuit board 10 by using, for example, a metal mask for solder printing.

The metal mask for solder printing is a plate-like member comprising opening parts provided in predetermined positions, and by filing the solder paste 30 in the opening parts and removing the metal mask for solder printing, the solder paste 30 is applied to the predetermined positions. The solder paste 30 is, as shown in FIG. 3, applied to the solder loading lands 26 in a substantially rectangular parallelepiped form.

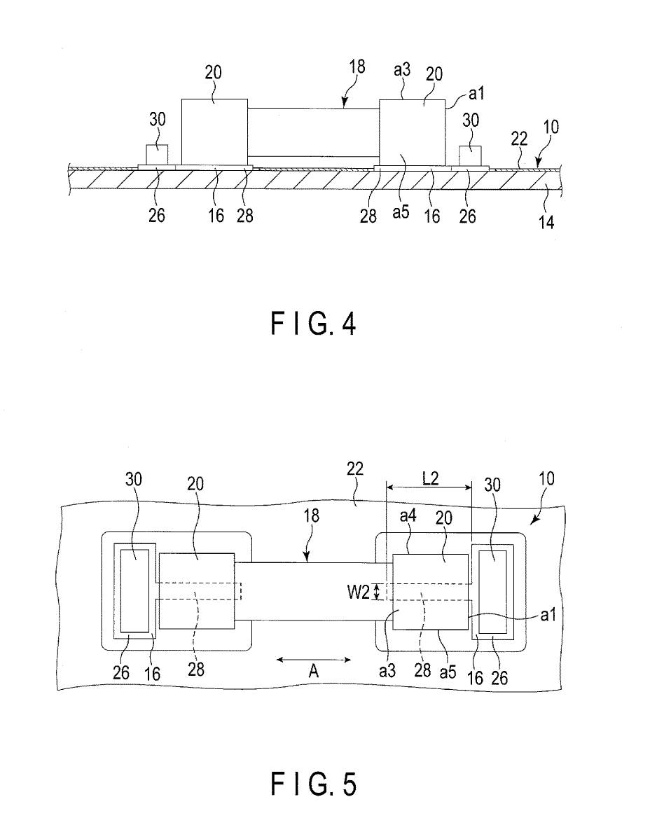

FIG. 4 is a side view of a state where the ceramic capacitor 18 and the solder paste 30 are provided on the circuit board 10. FIG. 5 is a plan view of a state where the ceramic capacitor 18 and the solder paste 30 are provided on the circuit board 10.

The ceramic capacitor 18 is provided in such a manner that the connection terminals 20 are overlaid on the attachment lands 28. The solder paste 30 is provided on the solder loading lands 26 in such a manner as to avoid contact with the connection terminals 20.

As shown in FIGS. 4 and 5, after the ceramic capacitor 18 and the solder paste 30 are provided on the circuit board 10, the circuit board 10 is heated in a reflow oven or the like to melt the granular solder contained in the solder paste 30. The solder paste 30 containing melt granular solder (hereinafter referred to as molten solder 31) flows from the solder loading lands 26 to the attachment lands 28 and contacts the outer terminal surfaces a1 of the connection terminals 20 of the ceramic capacitor 18.

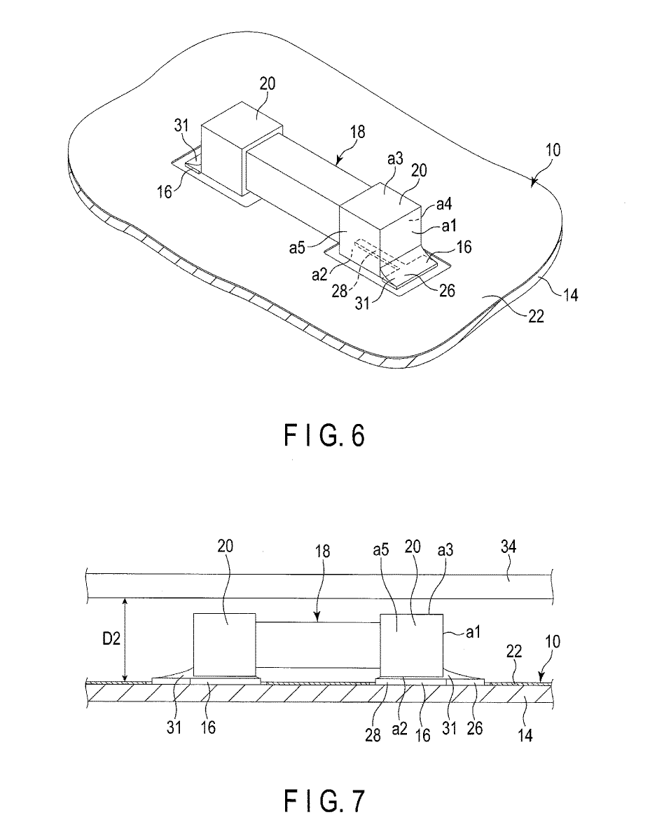

Further, the molten solder 31 partly adheres to the outer terminal surfaces a1 as shown in FIG. 6 and further flows into gaps formed between the lower terminal surfaces a2 of the connection terminals 20 and the attachment lands 28 by capillary action as shown in FIG. 7. Then, the circuit board 10 is cooled to a predetermined temperature or below, and the molten solder 31 that has flowed into the gaps between the lower terminal surfaces a2 and the attachment lands 28 is solidified.

Next, a method of soldering components to the circuit board 10 will be described by taking the ceramic capacitor 18 as an example. As shown in FIG. 2, the lands 16 corresponding to the connection terminals 20 of the ceramic capacitor 18 are formed on the circuit board 10. The lands 16 are formed on the circuit board 10 in a method similar to conventional methods.

On the upper surfaces of the solder loading lands 26 of the lands 16, solder paste 30 is provided as shown in FIGS. 2 and 3. The solder paste 30 is applied by using a metal mask for solder printing which comprises opening parts in positions corresponding to the solder loading lands 26. The solder paste 30 is provided on the solder loading lands 26 in a method similar to conventional methods. Note that the method of providing the solder paste 30 on the circuit board 10 is not necessarily limited to the above-described method.

After the solder paste 30 is provided on the solder loading lands 26, the ceramic capacitor 18 is mounted on the attachment positions of the circuit board 10. The ceramic capacitor 18 is provided on the circuit board 10 in such a manner that the lower terminal surfaces a2 of the ceramic capacitor 18 contact the attachment lands 28. When the ceramic capacitor 18 is provided on the circuit board 10, the connection terminals 20 do not contact the solder paste 30. Note that the solder paste 30 and the ceramic capacitor 18 may be slightly in contact with each other in a state where the ceramic capacitor 18 is provided on the circuit board 10 so that the ceramic capacitor 18 is provisionally fixed to the circuit board 10.

After the ceramic capacitor 18 and the solder paste 30 are provided on the circuit board 10, the circuit board 10 is heated in a reflow oven. When the granular solder of the solder paste 30 melts and becomes liquefied by heating, the molten solder 31 flows in all directions. Further, the molten solder 31 runs down with the help of the attachment lands 28 and contacts the connection terminals 20 of the ceramic capacitor 18. The molten solder 31 then flows into gaps formed between the lower terminal surfaces a2 and the attachment lands 28 by capillary action. In this way, as shown in FIG. 7, thin layers of the molten solder 31 having substantially an even thickness are formed between the connection terminals 20 and the attachment lands 28.

When the layers of the molten solder 31 are formed between the connection terminals 20 and the lands 16, the circuit board 10 is cooled. When the circuit board 10 is cooled to a predetermined temperature and the molten solder 31 is solidified, the connection terminals 20 and the lands 16 are electrically connected with each other, and the ceramic capacitor 18 is fixed to the circuit board 10.

According to the circuit board 10 of the first embodiment, the molten solder 31 flows into gaps between the lands 16 and the connection terminals 20 by capillary action, and then the ceramic capacitor 18 is soldered to the circuit board 10. Consequently, the ceramic capacitor 18 is attracted by the capillary action of the molten solder 31, and the height from the circuit board 10 to the upper end of the ceramic capacitor 18 is reduced. Further, since thin and even solder layers are formed between the lands 16 and the connection terminals 20, the height of the ceramic capacitor 18 will not be variable but can be maintained constant at all times.

Therefore, it is no longer necessary to provide an unnecessary space above the circuit board 10 for variations in the total height of the ceramic capacitor 18, and thus it is possible to narrow a gap D2 between the circuit board 10 and the housing 34 shown in FIG. 7 and to reduce the thickness of the tablet computer 12.

According to the circuit board 10, it is possible to flow the molten solder 31 reliably between the connection terminals 20 of the ceramic capacitor 18 and the lands 16 of the circuit board 10, and thus the occurrence of a soldering failure of the ceramic capacitor 18 can be reduced.

Further, according to the circuit board 10, width W2 of the attachment land 28 is less than width W1 of the connection terminal 20, and thus it is possible to attach the attachment land 28 to the lower terminal surface a2 of the connection terminal 20 with a less amount of solder.

Conventionally, in the case of applying the solder paste 30 with a metal mask for solder printing in such a manner as to partly reduce the amount of the solder paste 30, it have been difficult to apply the solder paste 30 as desired by simply reducing the size of an opening part formed in the metal mask for solder printing. In order to partly limit the amount of solder, advanced techniques such as a technique of partly reducing the thickness of the metal mask for solder printing and the like are required, and this has lead to an increase in cost. On the other hand, according to the circuit board 10 of the first embodiment, it is possible to appropriately limit the amount of solder to be applied to a necessary and sufficient amount.

Still further, according to the circuit board 10, it is possible, by adjusting width W2 and length L2 of the attachment land 28 and the like, to adjust the fixing power of solder and the attracting force of capillary action and to set the attachment strength and the thickness of solder appropriately. Further, it is also possible to wire densely by reducing width W2.

Still further, according to the circuit board 10, the ceramic capacitor 18 is always fixed to desired attachment positions. The reason is as follows. Suppose that the ceramic capacitor 18 is misaligned with the attachment positions of the circuit board 10. In this case, the attracting force of the capillary action (surface tension) of the molten solder 31 is produced unevenly from the attachment lands 28 and the like to the ceramic capacitor 18. The unevenness of the attracting force produced in this way acts in such a direction as to correct the position of the ceramic capacitor 18 with respect to the attachment lands 28 so that the attracting force produced from the attachment lands 28 becomes even, and consequently the ceramic capacitor 18 becomes fixed to the regular attachment positions.

Still further, according to the circuit board 10, the lands 16 can be formed without modifying conventional manufacturing methods. Further, the ceramic capacitor 18 can be soldered to the circuit board 10 by conventional soldering methods.

According to the first embodiment, it is possible to adopt conventional soldering methods of providing the solder paste 30 between components and the circuit board 10 as well as the soldering method of the present embodiment in soldering components onto the same circuit board 10, if necessary.

Still further, according to the first embodiment, it is possible to attach the attachment land 28 to the ceramic capacitor 18 with a less amount of solder by using capillary action in application of the molten solder 31 and reducing the connection area of the attachment land 28 to the lower terminal surface a2.

### Second Embodiment

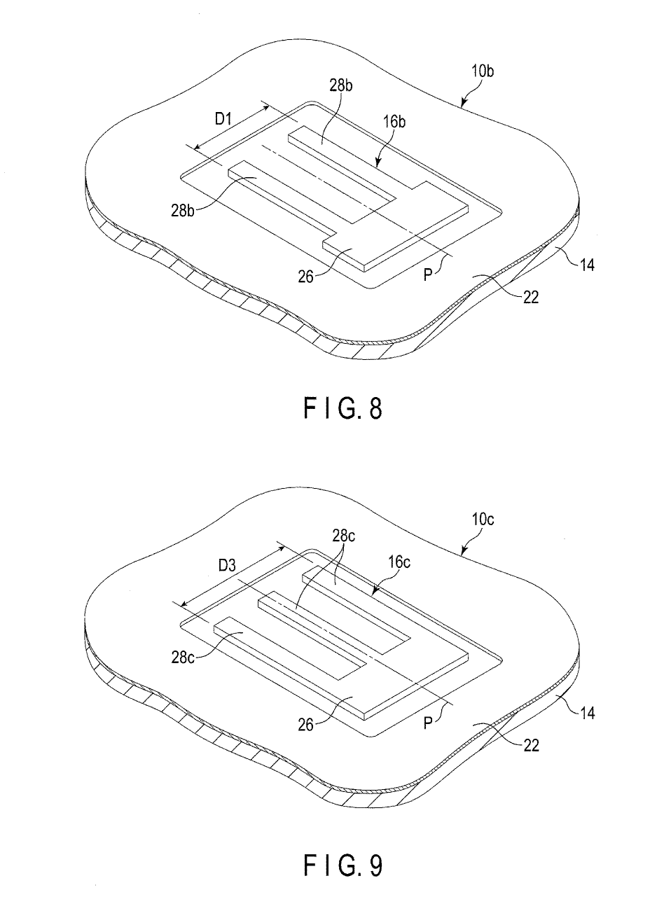

Next, a circuit board 10b of a second embodiment will be described. FIG. 8 illustrates the circuit board 10b of the second embodiment. The circuit board 10b comprises a land 16b. The land 16b comprises two attachment lands 28b with respect to a solder loading land 26. The solder loading land 26 has a structure similar to that of the solder loading land 26 of the first embodiment.

The two attachment lands 28b are provided perpendicularly to the longitudinal solder loading land 26, respectively. The two attachment lands 28b are symmetrical with respect to a center axis P of the solder loading land 26. The attachment lands 28b are provided with a gap D1 less than width W1 of a connection terminal 20 therebetween. The structures other than the above-described structures are similar to those of the first embodiment.

According to the circuit board 10b of the second embodiment, the lower terminal surface a2 is soldered to the upper surfaces of the pair of the attachment lands 28b, and thus the ceramic capacitor 18 can be soldered to the circuit board 10b stably and securely.

Further, the position of the ceramic capacitor 18 is corrected in such a manner that the force acts evenly to the connection terminal 20 from the attachment lands 28b provided on both sides of the solder loading lands 26. Therefore, even if the ceramic capacitor 18 is provided in a slanted manner with respect to the land 16b in a planar view, the position is corrected, and consequently the ceramic capacitor 18 is soldered to predetermined attachment positions.

### Third Embodiment

FIG. 9 illustrates a circuit board 10c of the third embodiment. On the circuit board 10c, one attachment land 28c is provided on a central axis P of a longitudinal solder loading land 26 and two attachment lands 28c are further provided on both sides thereof. The attachment lands 28c on both sides are provided with a gap D3 substantially equal to width W1 of the connection terminal 20 of the ceramic capacitor 18 therebetween.

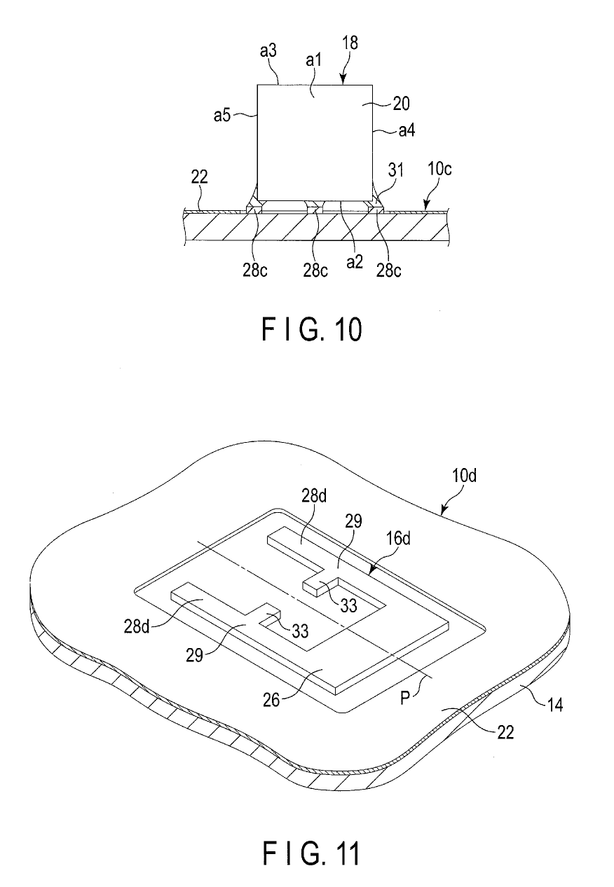

The solder loading land 26 has a structure similar to that of the solder loading land 26 of the first embodiment. According to the circuit board 10c, the ceramic capacitor 18 is soldered to the attachment land 18c provided in the center as well as to the attachment lands 18c provided on both sides as shown in FIG. 10. Therefore, the ceramic capacitor 18 can be soldered more stably and securely.

Further, the position of the ceramic capacitor 18 is corrected in such a manner that the force acts evenly to the connection terminal 20 from the attachment lands 28c provided on both side of the solder loading land 26. Therefore, even if the ceramic capacitor 18 is provided in a slanted manner with respect to the land 16c in a planar view, the position is corrected, and consequently the ceramic capacitor 18 is soldered to predetermined attachment positions.

### Fourth Embodiment

FIG. 11 illustrates a circuit board 10d of a fourth embodiment. On the circuit board 10d, an attachment land 28b of a land 16d comprises a first attachment land 29 extending in the longitudinal direction of the ceramic capacitor 18, and a second attachment land 33 extending perpendicularly to the first attachment land 29 from substantially the center of the first attachment land 29.

Two attachment lands 28d are provided on both sides of a central axis P of a solder loading land 26 on the right-hand side and the left-hand side in such a manner that the second attachment lands 33 face each other.

According to the circuit board 10d, the attachment lands 28d comprise the second attachment lands 33 extending in a direction perpendicularly to the longitudinal direction of the ceramic capacitor 18, and thus the ceramic capacitor 18 can be soldered to the circuit board 10d more stably and securely. The ceramic capacitor 18 is soldered to predetermined attachment positions.

### Fifth Embodiment

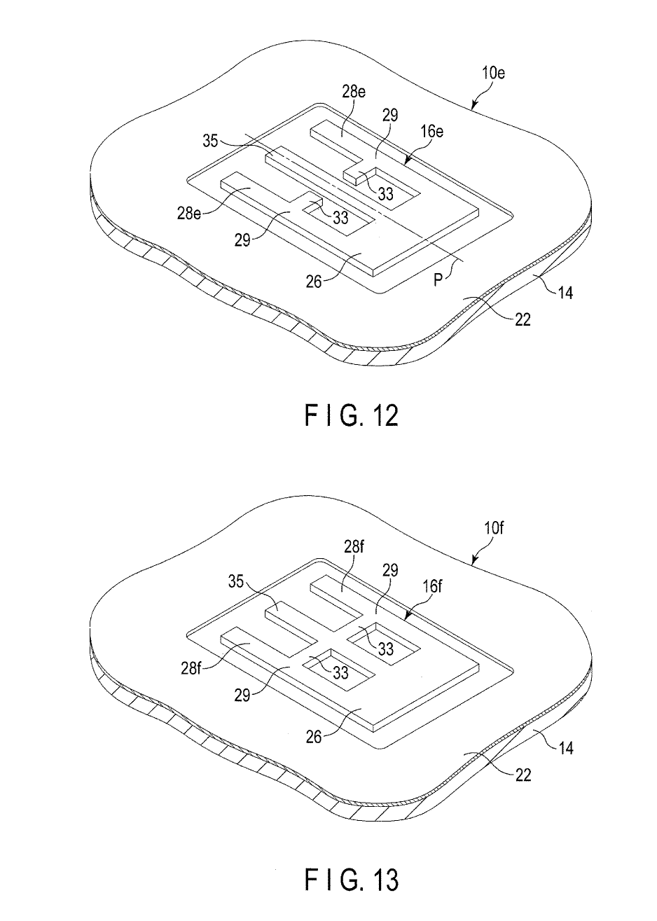

FIG. 12 illustrates a circuit board 10e of a fifth embodiment. The circuit board 10e has a structure in which a third attachment land 35 is added to a land similar to the land 16d of the circuit board 10d of the fourth embodiment on a central axis P of a solder loading land 26.

According to the circuit board 10e, the attachment lands 28e comprise portions extending in a direction perpendicularly to the longitudinal direction of the ceramic capacitor 18, and thus the ceramic capacitor 18 can be soldered to the circuit board 10e more stably and securely. The ceramic capacitor 18 is soldered to predetermined attachment positions.

### Sixth Embodiment

FIG. 13 illustrates a circuit board 10f of a sixth embodiment. The circuit board 10f has a structure in which second attachment lands 33 of a land similar to the land 16e of the circuit board 10e of the fifth embodiment are extended and connected to a third attachment land 35 provided in the center of a solder loading land 26.

According to the circuit board 10f, the attachment lands 28f comprise portions extending in a direction perpendicularly to the longitudinal direction of the ceramic capacitor 18, and thus the ceramic capacitor 18 can be soldered to the circuit board 10f more stably and securely. The ceramic capacitor 18 is soldered to predetermined attachment positions.

### Seventh Embodiment

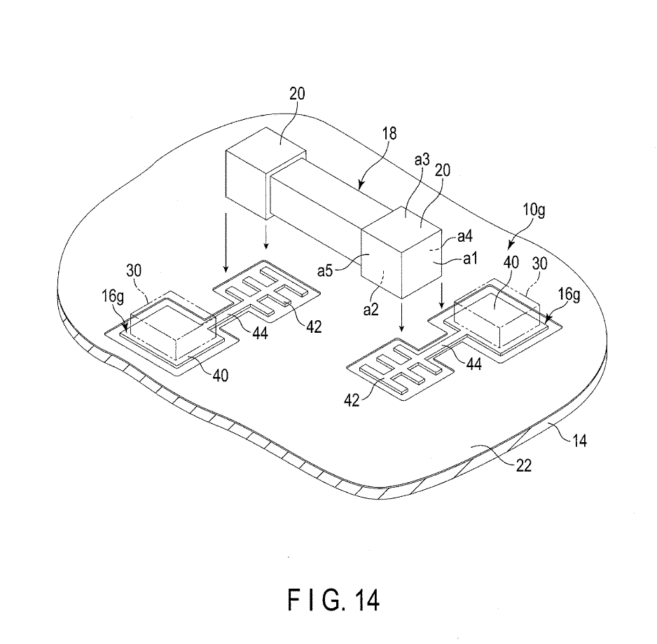

FIG. 14 illustrates an example of a circuit board 10g of a seventh embodiment. A land 16g of the circuit board 10g comprises a solder loading land 40, an attachment land 42, and a connection passage 44 which connects the solder loading land 40 and the attachment land 42. On the solder loading land 40, solder paste 30 is provided. The ceramic capacitor 18 is attached in such a manner that the lower terminal surfaces a2 of the connection terminals 20 are mounted on the attachment lands 42.

According to the circuit board 10g, when the circuit board 10g is heated, the granular solder of the solder paste 30 applied to the solder loading lands 40 melts, and the molten solder flows into the attachment lands 42 through the connection passages 44. The molten solder that has flowed into the attachment lands 42 then flows into gaps between the lower terminal surfaces a2 of the connection terminals 20 and the attachment lands 42 by capillary action and fixes the ceramic capacitor 18 to the circuit board 10g.

The solder loading lands 40 can be used as contact lands or the like for circuit testing of the circuit board 10g after the solder paste 30 runs off. According to the circuit board 10g, since there is no need to provide contact lands separately, it is possible to reduce variations in the mounting height of the ceramic capacitor 18 without lowering the wiring density.

Further, according to the circuit board 10g, the attachment land 42 comprises portions extending in a direction perpendicularly to the longitudinal direction of the ceramic capacitor 18, and thus the ceramic capacitor 18 can be soldered to the circuit board 10g more stably and securely. Since the areas of the solder loading lands 40 are large, the solder paste 30 can be provided easily. The ceramic capacitor 18 is soldered to predetermined attachment positions.

Further, in any of the above-described circuit boards of the second embodiment to the seven embodiment, since the ceramic capacitor 18 is fixed in place with the molten solder 31 that has flowed into gaps between the connection terminals 20 and the attachment lands 28 by the capillary action of the molten solder 31, the height of the circuit board 10 can be appropriately controlled, and consequently the thickness of the electronic device 12 can be reduced.

Note that, although the above description has been based on the assumption that each of the attachment lands 28b to 28g has an area less that the area of the lower terminal surface a2, this is in no way restrictive, and each of the attachment lands 28b to 28g may have an area greater than the area of the lower terminal surface a2. The solder loading land 26 has been assumed to be formed away from the outer terminal surface a1, but it is also possible to provide the lower terminal surface a2 on the solder loading land 26.

The above description has been based on the assumption that each of the attachment lands 28b to 28g is formed parallel to the longitudinal direction, but this is in no way restrictive. For example, it is possible to change the width, for example, by gradually increasing or reducing the width with distance from the solder loading land 26. Alternatively, it is possible to change the width, for example, by increasing or decreasing a portion in the middle portion of the longitudinal attachment land 28 in contrast to the other portion.

### Eighth Embodiment

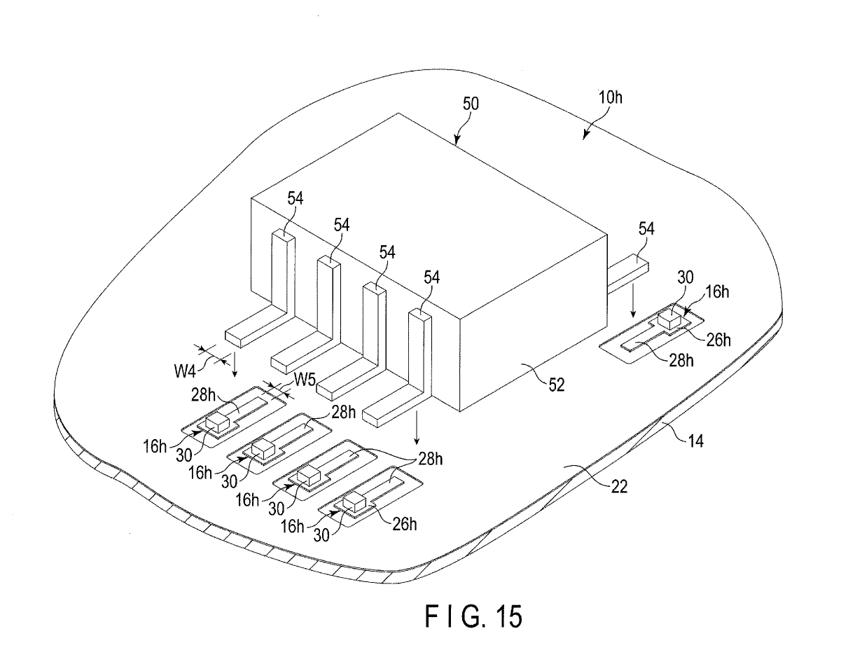

FIG. 15 illustrates an example of a circuit board 10h of an eighth embodiment. To the circuit board 10h, a component, namely, an IC chip 50 is to be attached. The circuit board 10h comprises lands 16h to which the IC chip 50 is to be attached. The IC chip 50 comprises connection terminals 54 on two side surfaces of a body 52 facing each other. The connection terminals 54 are made from metal, and four of which are provided on each of the side surfaces. The connection terminals 54 bend at the lower ends of the side surfaces of the body 52 and extend outward, respectively.

The circuit board 10h is provided with four pairs of lands 16h. Each land 16h is provided in such a manner as to correspond to the connection terminal 54. Each land 16h comprises a solder loading land 26h and an attachment land 28h. The solder loading land 26h and the attachment land 28h are connected to each other.

On the solder loading land 26h, solder paste 30 is provided. The attachment land 28h has a width W5 less than a width W4 of the connection terminal 54. In a state where the IC chip 50 is provided in predetermined attachment positions of the circuit board 10h, the connection terminals 54 are mounted on the attachment lands 28h and extend outward to the extent that the connection terminals 54 do not contact the solder paste 30.

In the eighth embodiment, the IC chip 50 is soldered in the following manner. The solder paste 30 is provided on the solder loading lands 26h. The connection terminals 54 of the IC chip 50 are mounted on the attachment lands 28h.

The circuit board 10h is heated in a reflow oven to melt the solder paste 30. The molten solder of the respective lands 16h flows from the respective solder loading lands 26h to the respective attachment lands 28h and contacts the connection terminals 54. Then, the molten solder flows into gaps between the connection terminals 54 and the attachment lands 28h by capillary action and is then solidified therein.

According to the eighth embodiment, the connection terminals 54 of the IC chip 50 are soldered to the lands 16h by the capillary action of the molten solder, and thus it is possible to attach the IC chip 50 to the circuit board 10h reliably with thin layers of solder. Therefore, there is no need to increase the mounting height of the IC chip 50, and thus the thickness of an electronic device comprising the circuit board 10h can be reduced.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A circuit board comprising:
a first land by an outer side of a connection terminal of a component mounted on the circuit board; and
a second land integrated with the first land, under a lower surface of the connection terminal, and having a width less than a width of the connection terminal, wherein
the second land is soldered to the connection terminal with a solder base that filled a gap between the second land and the connection terminal under capillary action.

2. The circuit board of claim 1, wherein
the first land is on the outer side of the connection terminal in a longitudinal direction, and
the second land extends from the first land in the longitudinal direction.

3. The circuit board of claim 2, wherein the second land is along a line crossing a center of the lower surface of the connection terminal.

4. The circuit board of claim 2, wherein the first land is integrated with a plurality of the second lands including the second land, and at least two of the plurality of the second lands are at an equal distance from a center line extending in the longitudinal direction.

5. The circuit board of claim 3, wherein a first pair of the first land and one of the plurality of the second lands is at an end of the component facing a second pair of the first land and one of the plurality of the second lands.

6. The circuit board of claim 4, wherein a first pair of the first land and one of the plurality of the second lands is at an end of the component facing a second pair of the first land and one of the plurality of the second lands.

7. The circuit board of claim 1, wherein the second land comprises a land extending in a longitudinal direction of the component and a land extending in a direction orthogonal to the longitudinal direction.

8. An electronic device comprising the circuit board of claim 1.

9. A method of soldering components comprising:
providing a solder base on a first land of a circuit board, the first land by an outer side of a connection terminal of a component to be mounted on the circuit board;
melting the solder base by heating and flowing the solder base into a gap between a second land of the circuit board and the connection terminal by capillary action, the second land integrated with the first land and under a lower surface of the connection terminal; and
fixing the connection terminal to the second land with the solder base.
